(19) United States
(12) Patent Application Publication
(10) Pub. No.: US 2025/0120289 A1
(43) Pub. Date: Apr. 10, 2025

(54) DISPLAY DEVICE

(71) Applicant: JDI Design and Development G.K., Tokyo (JP)

(72) Inventors: Kenji HARADA, Tokyo (JP); Yoshiyuki ONO, Tokyo (JP)

(73) Assignee: JDI Design and Development G.K., Tokyo (JP)

(21) Appl. No.: 18/906,229

(22) Filed: Oct. 4, 2024

(30) Foreign Application Priority Data
Oct. 5, 2023 (JP) 2023-173482

(51) Int. Cl. H10K 59/80; H10K 59/131

(52) U.S. Cl. CPC H10K 59/873; H10K 59/131

(57) ABSTRACT

A display device includes: an interlayer insulating layer on a substrate; an organic EL array; a metal layer connected to the organic EL array; a covering member disposed outward of the organic EL array and inward of a peripheral region of the interlayer insulating layer; a lower inorganic sealing layer provided continuously on the organic EL array, metal layer, and covering member up to the peripheral region of the interlayer insulating layer; a resin sealing layer covering at least part of the lower inorganic sealing layer; and an upper inorganic sealing layer provided continuously on the resin sealing layer up to the peripheral region of the interlayer insulating layer. At least part of a peripheral portion of the metal layer has a tapered cross-sectional shape convex in a direction opposite to a direction toward one principal surface of the substrate, and the peripheral portion is covered by the covering member.

### CROSS REFERENCE TO RELATED APPLICATION

The present application is based on and claims priority of Japanese Patent Application No. 2023-173482 filed on Oct. 5, 2023. The entire disclosure of the above-identified application, including the specification, drawings and claims is incorporated herein by reference in its entirety.

### FIELD

The present disclosure relates to a display device that includes a plurality of organic electroluminescent (EL) elements.

### BACKGROUND

Organic EL display panels including a plurality of organic EL elements are known. An organic EL element has a structure formed of thin films of various materials stacked on one another and includes a thin film transistor (TFT) substrate and a pixel electrode, a counter electrode and an organic light-emitting layer located between the electrodes, which are formed above the TFT substrate. An electron transport layer and other layers are also provided between the pixel electrode and the counter electrode. These layers may contain a material that deteriorates in light-emitting characteristics when the material reacts with moisture. In order to suppress deterioration of display quality of an organic EL display panel, it is required to suppress entry of moisture present in the external environment.

Patent Literature (PTL) 1 and 2 disclose sealing structures for suppressing entry of moisture present in the external environment in order to suppress deterioration of display quality of an organic EL display panel.

### CITATION LIST

### Patent Literature

PTL 1: Japanese Unexamined Patent Application Publication No. 2020-184426
PLT 2: Japanese Unexamined Patent Application Publication No. 2020-119842 SUMMARY

### Technical Problem

However, with the structure of the display devices disclosed in the patent literature, there are cases where moisture enters the inside of the display device.

The present disclosure provides a display device capable of suppressing the entry of moisture.

### Solution to Problem

A display device according to an aspect of the present disclosure includes: a substrate; an interlayer insulating layer that is provided on a side corresponding to one principal surface of the substrate and includes a resin material; an organic EL array that is provided on the interlayer insulating layer and includes a plurality of organic EL elements; a metal layer that is provided on the interlayer insulating layer, the metal layer being connected to the organic EL array and disposed outward of the organic EL layer; a covering member that is provided on the interlayer insulating layer, the covering member being disposed outward of the organic EL array and inward of a peripheral region of the interlayer insulating layer; a lower inorganic sealing layer that is provided continuously on the organic EL array, the metal layer, and the covering member and extends up to the peripheral region of the interlayer insulating layer to cover the organic EL array, the metal layer, and the covering member; a resin sealing layer that is provided inward of the peripheral region of the interlayer insulating layer and covering at least part of the lower inorganic sealing layer that is located on the organic EL array and the metal layer; and an upper inorganic sealing layer that is provided continuously on the resin sealing layer and extends up to the peripheral region of the interlayer insulating layer to cover the resin sealing layer and overlap the lower inorganic sealing layer at the peripheral region of the interlayer insulating layer, wherein at least part of a peripheral portion of the metal layer has a tapered cross-sectional shape that is convex in a direction opposite to a direction toward the one principal surface of the substrate, the peripheral portion being covered by the covering member.

### Advantageous Effects

The display device according to the present disclosure is capable of suppressing the entry of moisture to the inside of the display device.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view schematically illustrating a display device according to a comparative example.

FIG. 2 is a cross-sectional view of the display device according to the comparative example.

FIG. 3 is an enlarged view of an opening of a metal layer of the display device according to the comparative example.

FIG. 4 is a plan view schematically illustrating a display device according to an embodiment.

FIG. 5 is a cross-sectional view of the display device according to the embodiment.

FIG. 6 is an enlarged view of a covering member provided on a peripheral portion of a metal layer of the display device according to the embodiment.

FIG. 7 is an enlarged view of a covering member provided to an opening of the metal layer of the display device according to the embodiment.

FIG. 8 is a diagram illustrating another example of the covering member provided to the opening of the metal layer according to the embodiment.

FIG. 9 is a plan view schematically illustrating a display device according to a variation of the embodiment.

FIG. 10 is a cross-sectional view of the display device according to the variation of the embodiment.

FIG. 11 is an enlarged view of a covering member provided on a peripheral portion of a metal layer of the display device according to the variation of the embodiment.

FIG. 12 is an enlarged view of a covering member provided to an opening of the metal layer of the display device according to the variation of the embodiment.

### DESCRIPTION OF EMBODIMENT

### (Circumstances Leading to the Present Disclosure)

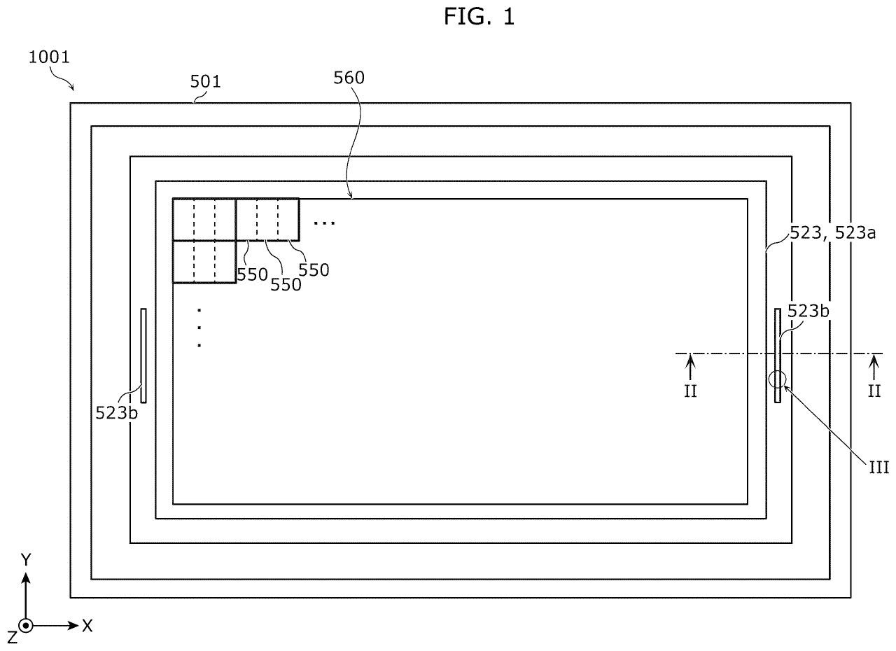

The circumstances leading to the present disclosure will be described with reference to FIG. 1 to FIG. 3.

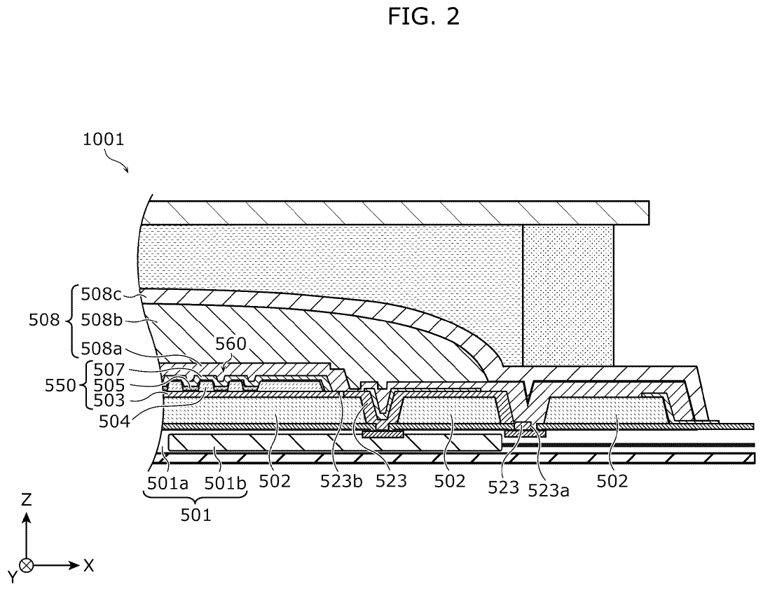

FIG. 1 is a plan view schematically illustrating display device 1001 according to a comparative example. FIG. 2 is a cross-sectional view of display 1001 according to the comparative example.

It should be noted that FIG. 1 is a top perspective view of organic EL array 560 and metal layer 523 included in display device 1001. FIG. 2 shows a cross section of display device 1001 taken along line II-II in FIG. 1.

Display device 1001 according to the comparative example includes substrate 501, interlayer insulating layer 502, pixel electrode 503, bank 504, light-emitting layer 505, counter electrode 507, metal layer 523, and sealing layer 508.

Substrate 501 is formed by base 501a and TFT layer 501b formed on base 501a. Sealing layer 508 has a three-layer structure including first sealing layer 508a made of silicon nitride (SiN), second sealing layer 508b made of resin, and third sealing layer 508c made of silicon nitride.

Metal layer 523 is a wiring layer connected to pixel electrodes 503 of organic EL elements 550 included in organic EL array 560. In the drawing, slit-like openings 523b are formed in regions of metal layer 523 that are located outward of organic EL array 560. Openings 523b are provided for vaporization of moisture in interlayer insulating layer 502 in the manufacturing process of display device 1001.

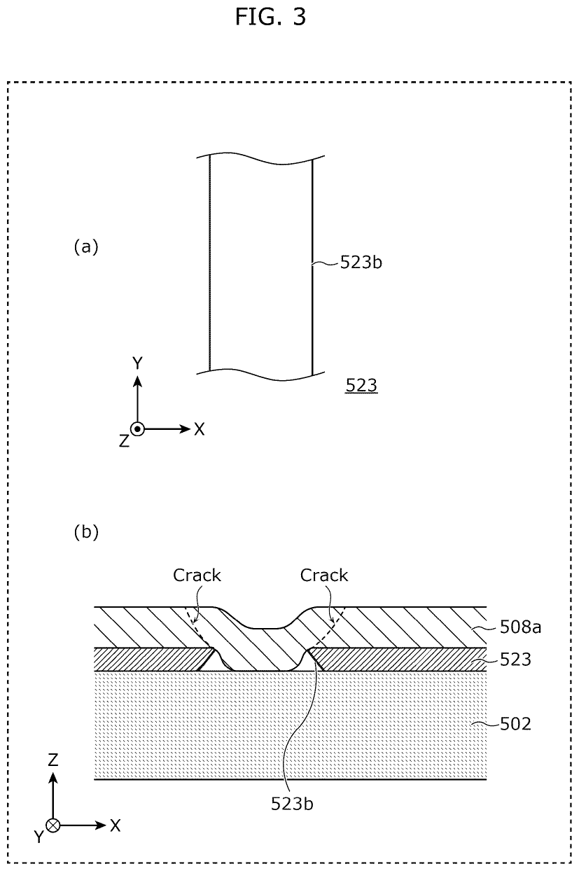

FIG. 3 is an enlarged view of opening 523b of metal layer 523 of display device 1001 according to the comparative example. This drawing is an enlarged view of part III in FIG. 1. Part (a) of FIG. 3 is a plan view, and Part (b) of FIG. 3 is a side cross-sectional view.

When opening 523b is formed in metal layer 523, a crack or other break may be formed in first sealing layer 508a when forming first sealing layer 508a on opening 523b (see Part (b) of FIG. 3). If a crack is formed in first sealing layer 508a, a problem arises that moisture enters through the crack and causes deterioration of display quality of display device 1001.

It is considered that a crack or other break is formed in first sealing layer 508a because the cross-sectional shape of opening 523b is a reverse tapered shape. The side surfaces of opening 523b form a reverse tapered shape because when forming opening 523b by etching using a resist mask, lower parts of metal layer 523, which are more distant from the resist mask, are exposed to more etchant and therefore are more strongly etched.

In addition, for example, when metal layer 523 is formed by a structure formed by a stack of an aluminum layer and a tungsten layer formed on the aluminum layer, aluminum is etched faster than tungsten, and therefore, the inner side surface of the tungsten layer projects inside the opening beyond the inner side surface of the aluminum layer.

Thus, it is considered that if first sealing layer 508a is formed on opening 523b having the reverse tapered shape, a space that is not filled with the sealing material is formed at the corners at the bottom of opening 523b, so that a slip of the sealing material occurs to form a crack or other break.

The crack is formed not only at opening 523b of metal layer 523 but also at peripheral portion 523a of metal layer 523, which has a tapered cross-sectional shape. Peripheral portion 523a of metal layer 523 is located closer to the outside air and is more susceptible to entry of moisture present in the external environment.

In response, a display device according to the present disclosure has the subsequent configuration in order to suppress the entry of moisture to the inside of the display device.

Hereinafter, embodiments of the display device according to the present disclosure will be described with reference to the Drawings. Each of the embodiments described below illustrates a specific example of the present disclosure. Therefore, numerical values, elements, the arrangement and connection of the elements, etc., described in the following embodiments are mere examples and are not intended to limit the present disclosure. Among the elements described in the following embodiments, elements not recited in any one of the independent claims are described as optional elements.

Elements which are substantially the same have the same reference signs in the figures. Moreover, the drawings are schematic illustrations and thus the scaling, etc., of respective parts is not necessarily represented precisely.

In the Written Description, the X direction, the Y direction, and the Z direction in the figures are row direction, the column direction, the thickness direction of the display device, respectively.

### Embodiment

### [Configuration of Display Device]

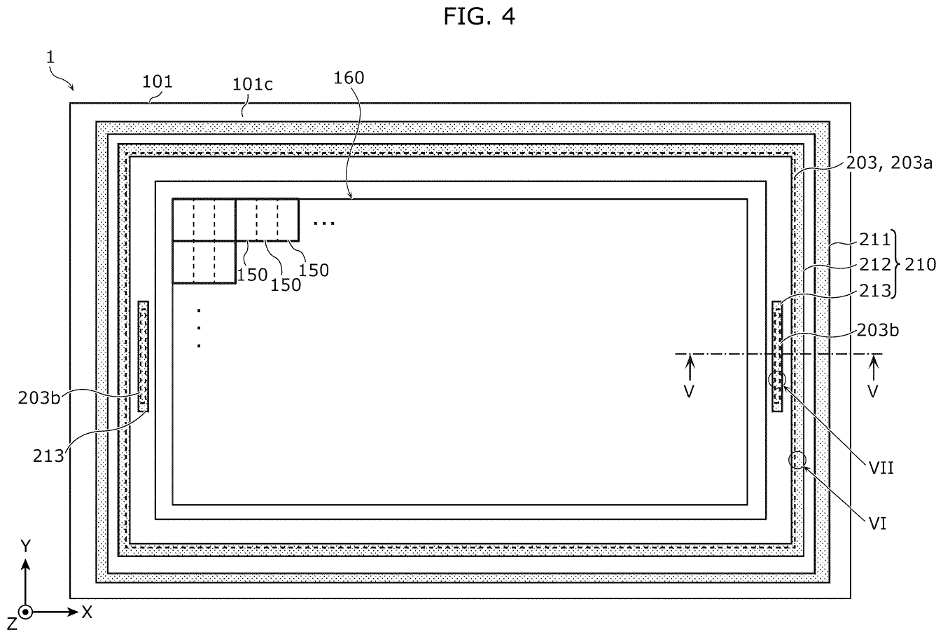

A display device according to an embodiment will be described with reference to FIG. 4 to FIG. 8.

FIG. 4 is a plan view schematically illustrating display device 1 according to the embodiment.

It should be noted that this drawing is a top perspective view of display device 1 with upper sheet member 110, adhesive layer 109, sealing layer 108, and dam member 115 removed, that is, a top perspective view of organic EL array 160, metal layer 203, and covering member 210. In addition, in this drawing, the position and width of covering member 210 are schematically illustrated.

Display device 1 illustrated in FIG. 4 is an example of an organic EL display panel and is rectangular in shape in plan view. In this embodiment, a display device of the top emission type, which emits light from the top surface thereof, will be described, for example.

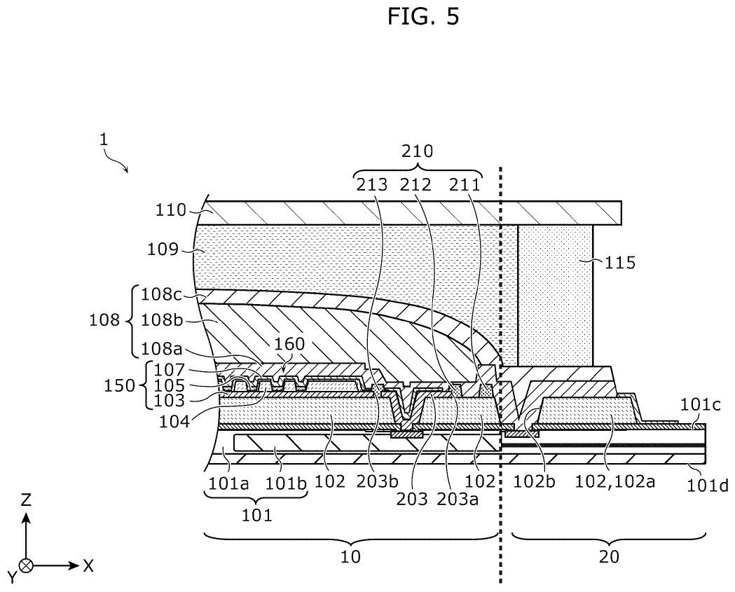

FIG. 5 is a cross-sectional view of display device 1. FIG. 5 illustrates a cross-section taken along line V-V in FIG. 4.

In display device 1, interlayer insulating layer 102 is formed on top of substrate 101, and organic EL array 160 is formed on top of interlayer insulating layer 102. Adhesive layer 109 and sheet member 110 are stacked in this order on organic EL array 160. Dam member 115 for holding back adhesive layer 109 is provided outward of adhesive layer 109.

It should be noted that in this embodiment, “inward” means toward the center of organic EL array 160 when viewed from a subject, and “outward” means the opposite side to the center of organic EL array 160 when viewed from a subject.

Substrate 101 is formed by base 101a that is made of an insulating material and thin film transistor (TFT) layer 101b. A drive circuit formed by a TFT is formed on TFT layer 101b. The TFT layer is formed by a channel, a gate insulating layer, a gate electrode, a protection layer, a source electrode, a drain electrode, and a passivation layer (not shown), for example.

Display device 1 has first region 10 including a central portion of display device 1 and second region 20 located in an outer periphery of first region 10. First region 10 is a region including TFT layer 101b of substrate 101 and is rectangular in shape. Second region 20 is a region in which TFT layer 101b is not formed and is in the shape of a frame. In second region 20, a plurality of wires and terminals for electrically connecting TFT layer 101b and an external drive circuit are provided (not illustrated).

In first region 10 of display device 1, a part of substrate 101, a part of interlayer insulating layer 102, organic EL array 160, bank 104, metal layer 203, covering member 210, a part of sealing layer 108, and a part of sheet member 110 are provided. In second region 20, a part of substrate 101, a part of interlayer insulating layer 102, a part of sealing layer 108, a part of adhesive layer 109, a part of sheet member 110, and dam member 115 are provided.

Substrate 101 has one principal surface 101c and another principal surface 101d that is opposite to one principal surface 101c. Display device 1 is formed by stacking a plurality of layers on one principal surface 101c of substrate 101.

Display device 1 includes substrate 101, interlayer insulating layer 102, organic EL array 160, bank 104, metal layer 203, covering member 210, and sealing layer 108 described above. Display device 1 further includes adhesive layer 109, sheet member 110, and dam member 115.

Interlayer insulating layer 102 is provided on the side of substrate 101 corresponding to one principal surface 101c. Interlayer insulating layer 102 is a layer made of an insulating resin material. The resin material may be acrylic resin, polyimide resin, siloxane resin, or phenolic resin, for example. Interlayer insulating layer 102 is also a layer for planarizing the difference in height due to formation of TFT layer 101b.

Interlayer insulating layer 102 is formed across first region 10 and second region 20 on substrate 101. In interlayer insulating layer 102 in second region 20, peripheral groove 102b is formed to surround first region 10. In the following, interlayer insulating layer 102 provided in second region 20 excluding peripheral groove 102b will be referred to as peripheral region 102a of interlayer insulating layer 102.

Organic EL array 160 is provided in first region 10 on interlayer insulating layer 102. Organic EL array 160 is formed by a plurality of organic EL elements 150 disposed in a matrix. With organic EL array 160, three organic EL elements 150 corresponding to the colors of RGB (red, green, and blue) form three subpixels, which are combined to form one pixel. It should be noted that each pixel is not exclusively formed by three subpixels and may be formed by one subpixel corresponding to W (white) or four subpixels corresponding to the colors of RGBW.

Each organic EL element 150 has pixel electrode 103, light-emitting layer 105, and counter electrode 107.

Pixel electrode 103 is an electrode that serves as a positive electrode of organic EL element 150. Pixel electrode 103 includes a metal layer made of a metal material having light reflectivity and is formed on interlayer insulating layer 102. Pixel electrode 103 is provided for each pixel and electrically connected to TFT layer 101b via a connection electrode. Pixel electrode 103 may be formed by the metal layer alone or may have a structure formed by a plurality of layers stacked.

Light-emitting layer 105 is provided on pixel electrode 103. Light-emitting layer 105 is formed by a polymeric material or a monomeric material. Light-emitting layer 105 is formed in an opening of bank 104 and emits light of colors R, G, and B through recombination of positive holes and electrons.

Counter electrode 107 is an electrode that serves as a negative electrode of organic EL element 150. Counter electrode 107 is made of a conductive material having translucency. The material of counter electrode 107 may be ITO or IZO, for example. It should be noted that as the material of counter electrode 107, a thin film of a metal, such as silver, silver alloy, aluminum, or aluminum alloy, may also be used. It should be noted that an electron transport layer or the like is formed between light-emitting layer 105 and counter electrode 107 (not illustrated).

Bank 104 is in the shape of a frame-like partition wall and is provided on pixel electrode 103 to surround light-emitting layer 105 and counter electrode 107 of organic EL element 150. Bank 104 is made of an insulating organic material, such as acrylic resin, polyimide resin, novolac resin, or phenolic resin.

Metal layer 203 is provided on a part of interlayer insulating layer 102. Metal layer 203 is connected to organic EL array 160 and disposed outward of organic EL array 160. Specifically, metal layer 203 is connected to pixel electrode 103 of organic EL element 150. Metal layer 203 in this embodiment is provided in first region 10 and is not provided in second region 20.

Metal layer 203 has a multilayer structure including an aluminum layer and a tungsten layer formed on the aluminum layer. Metal layer 203 is formed by coating, sputtering, or vacuum deposition, for example. Metal layer 203 is made of the same material as pixel electrode 103. In addition, metal layer 203 is formed at the same level as pixel electrode 103. The configuration of metal layer 203 will be described in detail later.

Covering member 210 is a portion that is added to an edge of metal layer 203 and is provided on interlayer insulating layer 102. Covering member 210 is disposed outward of organic EL array 160 and inward of peripheral region 102a of interlayer insulating layer 102. Covering member 210 is provided in first region 10 and is not provided in second region 20. Covering member 210 is disposed outward of bank 104. Covering member 210 is made of the same material as bank 104. In addition, covering member 210 is formed at the same level as bank 104. The configuration of covering member 210 will also be described in detail later.

Sealing layer 108 has a function of protecting organic EL array 160 and the like. Sealing layer 108 is formed by lower inorganic sealing layer 108a having translucency, resin sealing layer 108b, and upper inorganic sealing layer 108c.

Lower inorganic sealing layer 108a is provided continuously on organic EL array 160, metal layer 203, and covering member 210 and extends up to peripheral region 102a of interlayer insulating layer 102 to cover organic EL array 160, metal layer 203, and covering member 210. Lower inorganic sealing layer 108a is formed in both first region 10 and second region 20. Lower inorganic sealing layer 108a is formed by a thin film of silicon nitride (SiN).

Resin sealing layer 108b covers a part of lower inorganic sealing layer 108a, or more specifically, at least a part of lower inorganic sealing layer 108a located on organic EL array 160 and metal layer 203. Resin sealing layer 108b is provided inward of peripheral region 102a of interlayer insulating layer 102. More specifically, resin sealing layer 108b is continuously provided up to a region inward of an outermost covering member (first covering member 211) of covering member 210. Resin sealing layer 108b is formed in first region 10 and is not provided in second region 20. Resin sealing layer 108b is made of fluorocarbon resin, acrylic resin, epoxy resin, or silicon resin, for example.

Upper inorganic sealing layer 108c is provided continuously on resin sealing layer 108b and extends up to peripheral region 102a of interlayer insulating layer 102 to cover resin sealing layer 108b and overlap lower inorganic sealing layer 108a in peripheral region 102a of interlayer insulating layer 102. Upper inorganic sealing layer 108c is formed in both first region 10 and second region 20. Upper inorganic sealing layer 108c is formed by a thin film of silicon nitride (SiN).

As described above, upper inorganic sealing layer 108c extends up to peripheral region 102a of interlayer insulating layer 102, and an outer edge portion of upper inorganic sealing layer 108c and an outer edge portion of lower inorganic sealing layer 108a are in intimate contact with each other.

Sheet member 110 is a member that augments the sealing of display device 1. Sheet member 110 is formed from a translucent material, such as a translucent resin film. Adhesive layer 109 is provided between sheet member 110 and sealing layer 108. Adhesive layer 109 is a material for bonding sheet member 110 to sealing layer 108 and is formed from acrylic resin having translucency. Sheet member 110 is aligned on sealing layer 108 and bonded to sealing layer 108 by adhesive layer 109.

Display device 1 according to this embodiment has the configuration described below in order to suppress entry of moisture from outside.

Covering member 210 has a plurality of covering members, specifically, first covering member 211, second covering member 212, and third covering member 213. It should be noted that the number of covering members 210 may be one, or four or more.

First covering member 211 is located at the outermost position among the plurality of covering members. Second covering member 212 is located inward of first covering member 211, and third covering member 213 is located inward of the second covering member. In other words, second covering member 212 is located outward of third covering member 213, and first covering member 211 is located outward of second covering member 212.

Each of first covering member 211 and second covering member 212 is in the shape of a frame and provided to surround organic EL array 160 and metal layer 203 on interlayer insulating layer 102.

Peripheral portion 203a of metal layer 203 is located inward of first covering member 211. At least a part of peripheral portion 203a of metal layer 203 has a tapered cross-sectional shape that is convex in a direction opposite to a direction toward one principal surface 101c of substrate 101. It should be noted that metal layer 203 in this embodiment is not provided between first covering member 211 and second covering member 212. Peripheral portion 203a including a peripheral edge of metal layer 203 is in contact with the inner side of second covering member 212 and is covered by covering member 210 (second covering member 212) that is in contact with peripheral portion 203a of metal layer 203. That is, second covering member 212 covers peripheral portion 203a of metal layer 203.

It should be noted that on interlayer insulating layer 102 located between first covering member 211 and second covering member 212, lower inorganic sealing layer 108a, resin sealing layer 108b, and upper inorganic sealing layer 108c are stacked in this order.

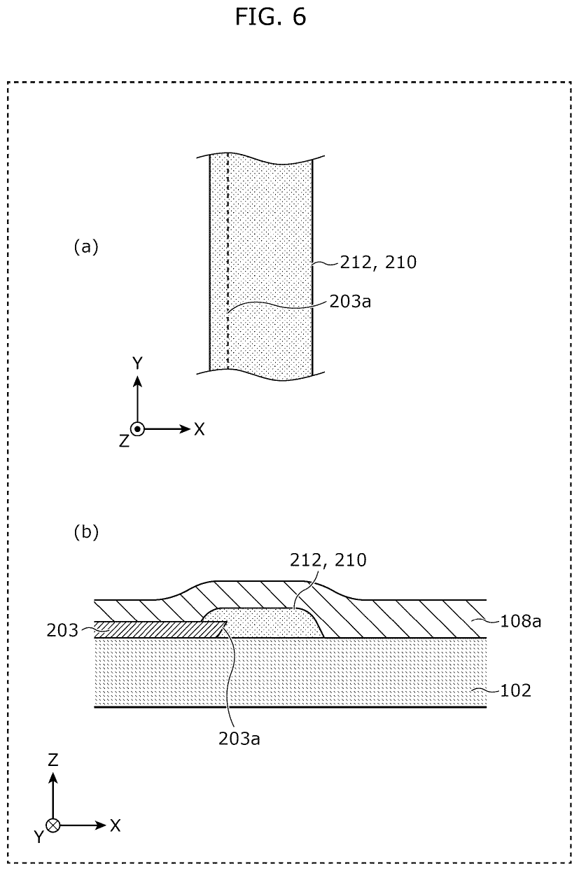

FIG. 6 is an enlarged view of covering member 210 provided on peripheral portion 203a of metal layer 203 of display device 1. This drawing is an enlarged view of part VI in FIG. 4. Part (a) of this drawing is a plan view, and Part (b) of this drawing is a cross-sectional view.

As illustrated in this drawing, peripheral portion 203a of metal layer 203 is covered by second covering member 212. Specifically, second covering member 212 covers a corner portion and a side surface of peripheral portion 203a of metal layer 203. Second covering member 212 has a tapered cross-sectional shape that is convex in the direction opposite to the direction toward one principal surface 101c of substrate 101. In addition, an upper part of second covering member 212 that is above metal layer 203 has a trapezoidal cross-sectional shape.

Although metal layer 203 is in a reverse tapered shape at the side surface of peripheral portion 203a, second covering member 212 covers the corner portion and the side surface of peripheral portion 203a, and the opposite side surfaces of the upper part of second covering member 212 form a forward tapered shape. Therefore, formation of a crack or other break in lower inorganic sealing layer 108a disposed on metal layer 203 and second covering member 212 can be suppressed. As a result, entry of moisture from outside can be suppressed.

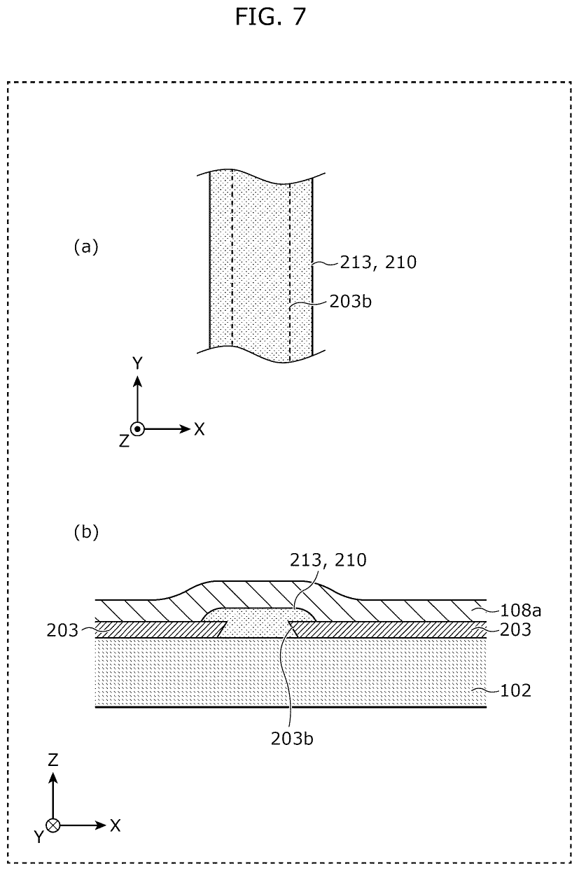

FIG. 7 is an enlarged view of covering member 210 provided to opening 203b of metal layer 203 of display device 1. This drawing is an enlarged view of part VII in FIG. 4. Part (a) of this drawing is a plan view, and Part (b) of this drawing is a cross-sectional view.

Metal layer 203 has opening 203b located inward of peripheral portion 203a of metal layer 203. In this example, opening 203b is formed outward of organic EL array 160 and bank 104 and inward of second covering member 212. Opening 203b is formed in metal layer 203 in order to discharge moisture in interlayer insulating layer 102 upward through opening 203b from the part of interlayer insulating layer 102 exposed in opening 203b during burning after deposition of the bank and light-emitting layer 105.

As illustrated in this drawing, opening 203b of metal layer 203 is covered by third covering member 213. Specifically, third covering member 213 covers corner portions and inner side surfaces of opening 203b of metal layer 203. Third covering member 213 has a tapered cross-sectional shape that is convex in the direction opposite to the direction toward one principal surface 101c of substrate 101. In addition, an upper part of third covering member 213 that is above metal layer 203 has a trapezoidal cross-sectional shape.

Although metal layer 203 is in a reverse tapered shape at the sides surface of opening 203b, third covering member 213 covers the corner portions and the side surfaces of opening 203b, and the opposite side surfaces of the upper part of third covering member 213 form a forward tapered shape. Therefore, formation of a crack or other break in lower inorganic sealing layer 108a disposed on metal layer 203 and third covering member 213 can be suppressed. As a result, entry of moisture from outside can be suppressed.

According to this embodiment, the whole of peripheral portion 203a and the whole of opening 203b are covered by covering member 210. It should be noted that covering member 210 may be provided for opening 203b as described below.

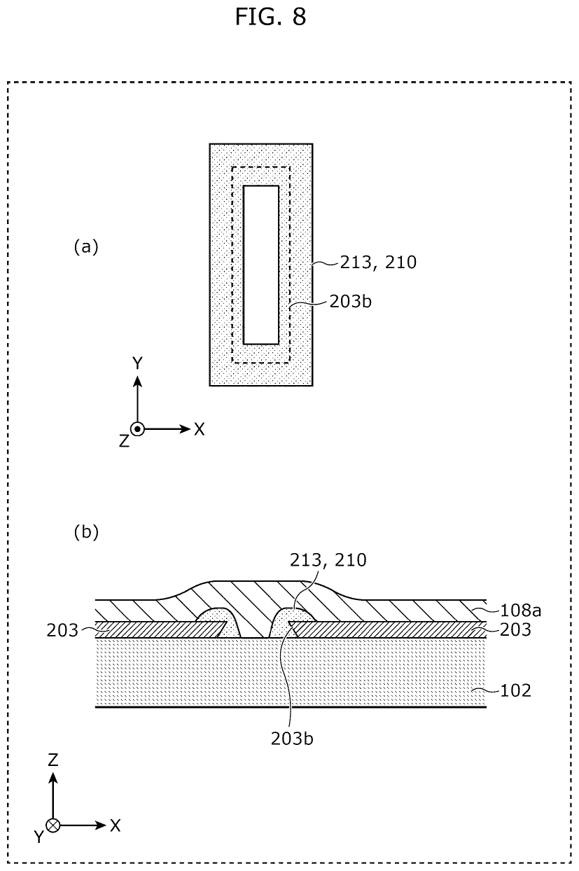

FIG. 8 is a diagram illustrating another example of covering member 210 provided to opening 203b of metal layer 203 of display device 1.

As illustrated in this drawing, the corner portions of opening 203b of metal layer 203 are covered by third covering member 213. Although metal layer 203 is in a reverse tapered shape at the side surfaces of opening 203b, third covering member 213 covers the corner portions of opening 203b. This arrangement can also reduce the surfaces in the reverse tapered shape. Therefore, formation of a crack or other break in lower inorganic sealing layer 108a disposed on metal layer 203 and third covering member 213 can be suppressed. As a result, entry of moisture from outside can be suppressed.

According to this embodiment, as described above, peripheral portion 203a or opening 203b of metal layer 203 is covered by covering member 210. In other words, on the surface on which lower inorganic sealing layer 108a is deposited, covering member 210 reduces the reverse tapered surface. Therefore, formation of a crack in lower inorganic sealing layer 108a disposed on metal layer 203 and covering member 210 can be suppressed. As a result, entry of moisture into display device 1 can be suppressed.

Next, an example of a method of forming covering member 210 will be described. Covering member 210 is made of the same material as bank 104 and is formed in the same layer at the same time as bank 104. Covering member 210 is formed by uniformly applying a solution of phenolic resin in a solvent (a mixed solvent of ethyl lactate and GBL, for example) onto pixel electrode 103 and interlayer insulating layer 102 by spin-coating or the like. Then, pattern exposure and development are performed to form covering member 210, which is then burned. The burning is performed at a temperature equal to or higher than 150° C. and equal to or lower than 210° C. for 60 minutes. Furthermore, in the process of forming covering member 210, the surface of covering member 210 may be subjected to a surface treatment with a predetermined alkaline solution, water, organic solvent or the like or a plasma treatment. This enables formation of covering member 210 having a tapered cross-sectional shape that is convex in the direction opposite to the direction toward one principal surface 101c of substrate 101.

### Variation of Embodiment

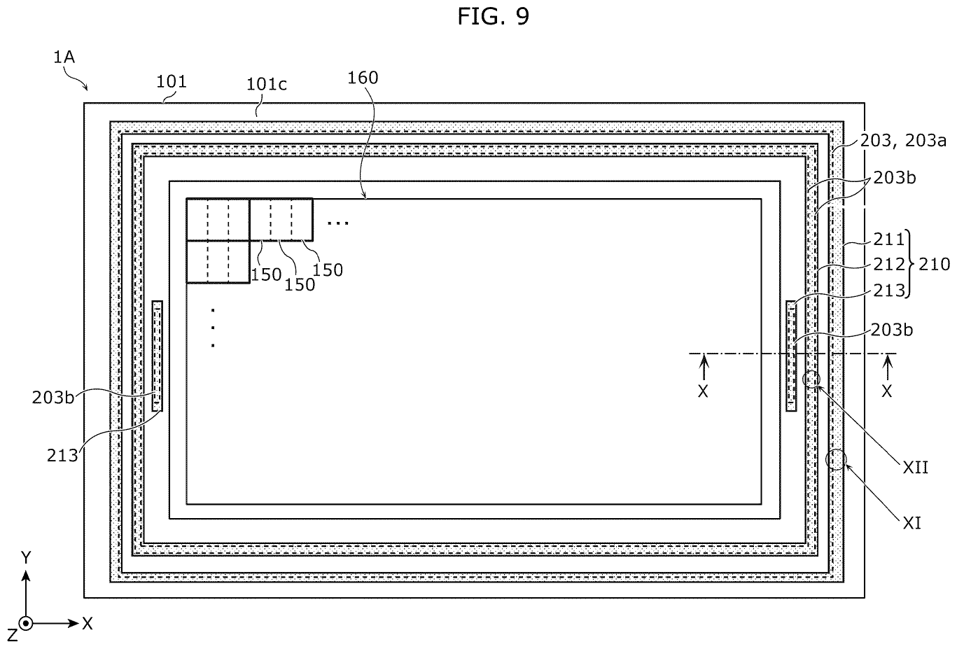

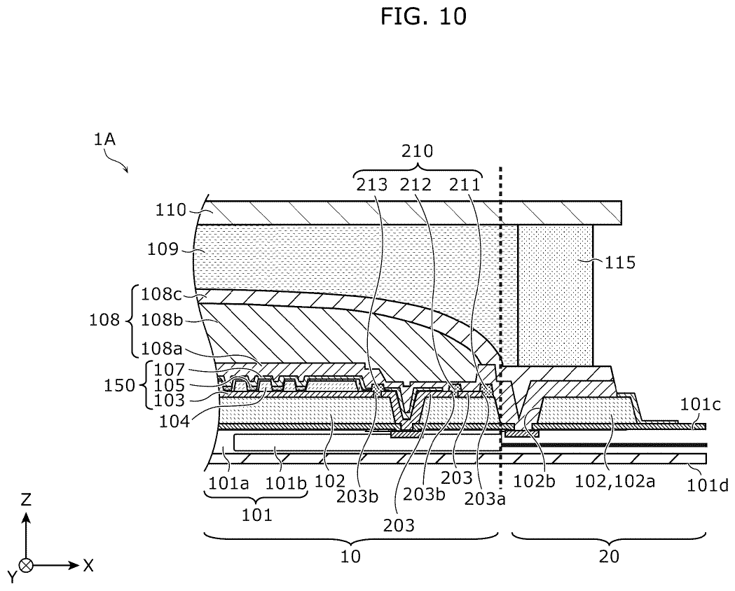

Display device 1A according to a variation of the embodiment will be described with reference to FIG. 9 and FIG. 10. In this variation, an example will be described in which peripheral portion 203a of metal layer 203 is covered by first covering member 211.

FIG. 9 is a plan view schematically illustrating display device 1A according to the variation of the embodiment.

It should be noted that this drawing is a top perspective view of display device 1A with upper sheet member 110, adhesive layer 109, sealing layer 108, dam member 115 and the like removed, that is, a top perspective view of organic EL array 160, metal layer 203, and covering member 210. In addition, in this drawing, the position and width of covering member 210 are schematically illustrated.

Display device 1A illustrated in FIG. 9 is an example of the organic EL display panel and is rectangular in shape in plan view. In this embodiment, again, a display device of the top emission type, which emits light from the top surface thereof, will be described, for example.

FIG. 10 is a cross-sectional view of display device 1A according to the variation of the embodiment. FIG. 10 illustrates a cross section taken along line X-X in FIG. 9.

In display device 1A, interlayer insulating layer 102 is formed on top of substrate 101, and organic EL array 160 is formed on top of interlayer insulating layer 102. Adhesive layer 109 and sheet member 110 are stacked in this order on organic EL array 160. Dam member 115 for holding back adhesive layer 109 is provided outward of adhesive layer 109.

Display device 1A includes substrate 101, interlayer insulating layer 102, organic EL array 160, bank 104, metal layer 203, covering member 210, and sealing layer 108. Display device 1A further includes adhesive layer 109, sheet member 110, and dam member 115. In the following, differences from the embodiment will be mainly described.

Display device 1A according to this variation have the configuration described below in order to suppress entry of moisture from outside.

Covering member 210 has a plurality of covering members, specifically, first covering member 211, second covering member 212, and third covering member 213. It should be noted that the number of covering members 210 may be one, or four or more.

First covering member 211 is located at the outermost position among the plurality of covering members. Second covering member 212 is located inward of first covering member 211, and third covering member 213 is located inward of the second covering member.

First covering member 211 is in the shape of a frame and provided to surround organic EL array 160 and metal layer 203 on interlayer insulating layer 102.

Peripheral portion 203a of metal layer 203 is located inward of first covering member 211. At least a part of peripheral portion 203a of metal layer 203 has a tapered cross-sectional shape that is convex in a direction opposite to a direction toward one principal surface 101c of substrate 101. In the variation, metal layer 203 is provided between first covering member 211 and second covering member 212. Peripheral portion 203a including a peripheral edge of metal layer 203 is in contact with the inner side of first covering member 211 and is covered by covering member 210 (first covering member 211) that is in contact with peripheral portion 203a of metal layer 203. That is, first covering member 211 covers peripheral portion 203a of metal layer 203.

It should be noted that metal layer 203 has no opening between first covering member 211 and second covering member 212. In the variation, metal layer 203 is provided between first covering member 211 and second covering member 212.

Specifically, metal layer 203 has no opening in a region within 200 μm from first covering member 211, and metal layer 203 is present in the whole of the region. On metal layer 203 between first covering member 211 and second covering member 212, lower inorganic sealing layer 108a, resin sealing layer 108b, and upper inorganic sealing layer 108c are stacked in this order.

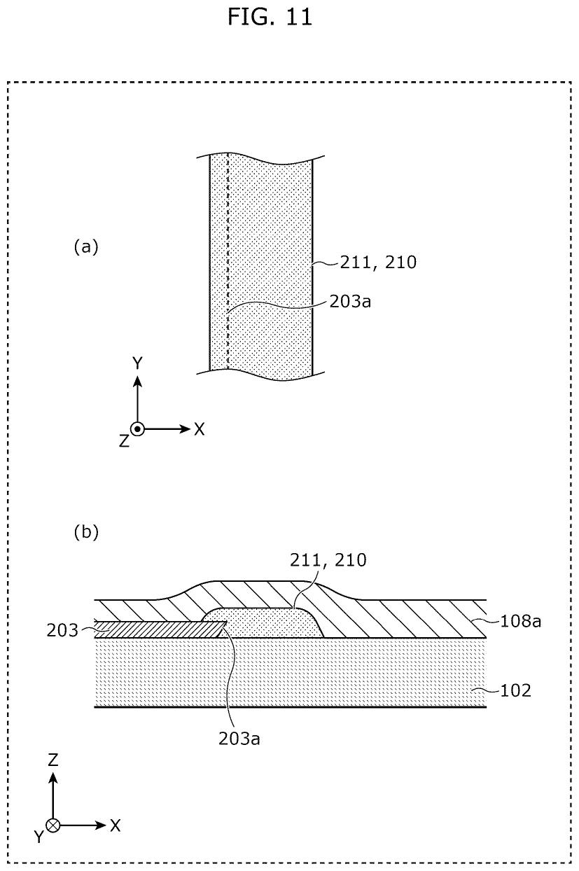

FIG. 11 is an enlarged view of covering member 210 provided on peripheral portion 203a of metal layer 203 of display device 1A. This drawing is an enlarged view of part XI in FIG. 9. This drawing illustrates basically the same structure as the structure in FIG. 6 illustrating the embodiment except that second covering member 212 is replaced with first covering member 211.

As illustrated in this drawing, peripheral portion 203a of metal layer 203 is covered by first covering member 211. Specifically, first covering member 211 covers a corner portion and a side surface of peripheral portion 203a of metal layer 203. First covering member 211 has a tapered cross-sectional shape that is convex in the direction opposite to the direction toward one principal surface 101c of substrate 101. In addition, an upper part of first covering member 211 that is above metal layer 203 has a trapezoidal cross-sectional shape.

Although metal layer 203 is in a reverse tapered shape at the side surface of peripheral portion 203a, first covering member 211 covers the corner portion and the side surface of peripheral portion 203a, and the opposite side surfaces of the upper part of first covering member 211 form a forward tapered shape. Therefore, formation of a crack or other break in lower inorganic sealing layer 108a disposed on metal layer 203 and first covering member 211 can be suppressed. As a result, entry of moisture from outside can be suppressed.

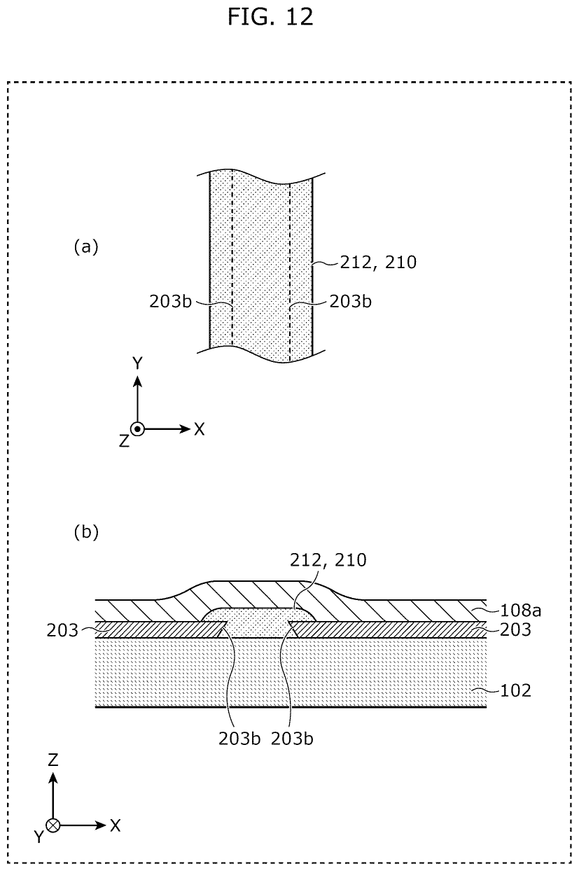

FIG. 12 is an enlarged view of covering member 210 provided to opening 203b of metal layer 203 of display device 1A. This drawing is an enlarged view of part XII in FIG. 9. This drawing illustrates basically the same structure as the structure in FIG. 7 illustrating the embodiment except that third covering member 213 is replaced with second covering member 212.

As illustrated in this drawing, opening 203b of metal layer 203 is covered by second covering member 212. Specifically, second covering member 212 covers corner portions and inner side surfaces of opening 203b of metal layer 203. Second covering member 212 has a tapered cross-sectional shape that is convex in the direction opposite to the direction toward one principal surface 101c of substrate 101. In addition, an upper part of second covering member 212 that is above metal layer 203 has a trapezoidal cross-sectional shape.

Although metal layer 203 is in a reverse tapered shape at the sides surface of opening 203b, second covering member 212 covers the corner portions and the side surfaces of opening 203b, and the opposite side surfaces of the upper part of second covering member 212 form a forward tapered shape. Therefore, formation of a crack or other break in lower inorganic sealing layer 108a disposed on metal layer 203 and second covering member 212 can be suppressed. As a result, entry of moisture from outside can be suppressed.

As described above, in the variation, peripheral portion 203a or opening 203b of metal layer 203 is covered by covering member 210. Therefore, formation of a crack or other break in lower inorganic sealing layer 108a disposed on metal layer 203 and covering member 210 can be suppressed. As a result, entry of moisture into display device 1A can be suppressed.

### CONCLUSION

The display device according to the present disclosure is exemplified below.

A display device according to Example 1 includes: substrate 101; interlayer insulating layer 102 that is provided on a side corresponding to one principal surface 101c of substrate 101 and includes a resin material; organic EL array 160 that is provided on interlayer insulating layer 102 and includes a plurality of organic EL elements 150; metal layer 203 that is provided on interlayer insulating layer 102 and connected to organic EL array 160 and disposed outward of organic EL layer 160; covering member 210 that is provided on interlayer insulating layer 102 and disposed outward of organic EL array 160 and inward of peripheral region 102a of interlayer insulating layer 102; lower inorganic sealing layer 108a that is provided continuously on organic EL array 160, metal layer 203, and covering member 210 and extends up to peripheral region 102a of interlayer insulating layer 102 to cover organic EL array 160, metal layer 203, and covering member 210; resin sealing layer 108b that is provided inward of peripheral region 102a of interlayer insulating layer 102 and covering at least part of lower inorganic sealing layer 108a that is located on organic EL array 160 and metal layer 203; and upper inorganic sealing layer 108c that is provided continuously on resin sealing layer 108b and extends up to peripheral region 102a of interlayer insulating layer 102 to cover resin sealing layer 108b and overlap lower inorganic sealing layer 108a at peripheral region 102a of interlayer insulating layer 102. At least part of peripheral portion 203a of metal layer 203 has a tapered cross-sectional shape that is convex in a direction opposite to a direction toward the one principal surface 101c of substrate 101, peripheral portion 203a being covered by covering member 210.

In this manner, since peripheral portion 203a of metal layer 203 is covered by covering member 210, it is possible to suppress the forming of cracks in lower inorganic sealing layer 108a disposed on metal layer 203 and covering member 210. Accordingly, entry of moisture to the inside of the display device can be suppressed.

A display device according to Example 2 is the display device according to Example 1, in which a cross-sectional shape of covering member 210 may be tapered and convex in the direction opposite to the direction heading toward one principal surface 101c of substrate 101.

In this manner, by way of covering member 210 having a tapered cross-sectional shape, lower inorganic sealing layer 108a can be formed continuously on metal layer 203 and covering member 210. Therefore, formation of a crack in lower inorganic sealing layer 108a can be suppressed. As a result, entry of moisture into the display device can be suppressed.

A display device according to Example 3 is the display device according to Example 1 or 2, and may further include: bank 104 provided to surround each of the plurality of organic EL elements 150. Covering member 210 may be made of same material as bank 104.

This enables bank 104 and covering member 210 to be formed at the same time. Accordingly, there is no need to provide a new layer for forming covering member 210, and thus covering member 210 can be formed by a simple process. Accordingly, a display device capable of suppressing the entry of moisture can be provided through a simple process.

A display device according to Example 4 is the display device according to any one of Examples 1 to 3 and may include: first region 10 including TFT layer 101b of substrate 101 and second region 20 located outward of first region 10. When seen from a direction perpendicular to substrate 101: covering member 210 and peripheral portion 203a of metal layer 203 may be located in first region 10; and peripheral region 102a of interlayer insulating layer 102 may be located in second region 20.

In this manner, by providing peripheral portion 203a of metal layer 203 in first region 10, peripheral portion 203a of metal layer 203 can be distanced from the external environment. Accordingly, places that may become cracked can be distanced from the external environment, and thus forming of cracks can be suppressed. Accordingly, entry of moisture to the inside of the display device can be suppressed.

Display device 1 according to Example 5 is the display device according to any one of Examples 1 to 4, in which covering member 210 may include first covering member 211 located furthest outward and second covering member 212 located inward of first covering member 211, and peripheral portion 203a of metal layer 203 may be located inward of first covering member 211 and covered by second covering member 212.

In this manner, since peripheral portion 203a of metal layer 203 is covered by second covering member 212, it is possible to suppress the forming of cracks in lower inorganic sealing layer 108a disposed on metal layer 203 and second covering member 212. Accordingly, entry of moisture to the inside of display device 1 can be suppressed.

Display device 1 according to Example 6 is the display device according to Example 5, in which metal layer 203 may include opening 203b located inward of peripheral portion 203a of metal layer 203, covering member 210 may further include third covering member 213 located inward of second covering member 212, and opening 203b of metal layer 203 may be covered by third covering member 213.

In this manner, since opening 203b of metal layer 203 is covered by third covering member 213, it is possible to suppress the forming of cracks in lower inorganic sealing layer 108a disposed on metal layer 203 and third covering member 213. Accordingly, entry of moisture to the inside of display device 1 can be suppressed.

In display device 1 according to Example 7, metal layer 203 need not necessarily be provided between first covering member 211 and second covering member 212, and lower inorganic sealing layer 108a, resin sealing layer 108b, and upper inorganic sealing layer 108c may be stacked, in stated order, on interlayer insulating layer 102.

If an opening of metal layer 203 is provided between first covering member 211 and second covering member 212, for example, when forming resin sealing layer 108b in a wet film formation process, such as ink jetting, the opening inhibits the film formation, which uses the wetting and spreading of the resin sealing material. In this example, metal layer 203 is not provided between first covering member 211 and second covering member 212, so that no opening is provided, and therefore, the film formation can be achieved by taking advantage of the flowability of the resin sealing material. Therefore, resin sealing layer 108b can be appropriately formed, and entry of moisture into display device 1 can be suppressed.

Display device 1A according to Example 8 is the display device according to any one of Examples 1 to 4, in which covering member 210 may include first covering member 211 located furthest outward and second covering member 212 located inward of first covering member 211, and peripheral portion 203a of metal layer 203 may be covered by first covering member 211.

In this manner, since peripheral portion 203a of metal layer 203 is covered by first covering member 211, it is possible to suppress the forming of cracks in lower inorganic sealing layer 108a disposed on metal layer 203 and first covering member 211. Accordingly, entry of moisture to the inside of display device 1A can be suppressed.

Display device 1A according to Example 9 is the display device according to Example 8, in which metal layer 203 may include opening 203b located inward of peripheral portion 203a of metal layer 203, and opening 203b of metal layer 203 may be covered by second covering member 212.

In this manner, since opening 203b of metal layer 203 is covered by second covering member 212, it is possible to suppress the forming of cracks in lower inorganic sealing layer 108a disposed on metal layer 203 and second covering member 212. Accordingly, entry of moisture to the inside of display device 1A can be suppressed.

Display device 1A according to Example 10 is the display device according to Example 9, in which an opening need not be provided between first covering member 211 and second covering member 212, metal layer 203 may be provided throughout an entire area between first covering member 211 and second covering member 212, and lower inorganic sealing layer 108a, resin sealing layer 108b, and upper inorganic sealing layer 108c may be stacked, in stated order, on metal layer 203.

If an opening of metal layer 203 is provided between first covering member 211 and second covering member 212, for example, when forming resin sealing layer 108b in a wet film formation process, such as ink jetting, the opening inhibits the film formation, which uses the wetting and spreading of the resin sealing material. In this example, no opening is provided in metal layer 203, and therefore, the film formation can be achieved by taking advantage of the flowability of the resin sealing material. Therefore, resin sealing layer 108b can be appropriately formed, and entry of moisture into display device 1A can be suppressed.

Display device 1A according to Example 11 is the display device according to Example 9 or 10, in which an opening need not be provided in a region of metal layer 203 that is 200 μm inward from first covering member 211, and metal layer 203 may be provided in an entirety of the region.

If an opening of metal layer 203 is provided in a region that is 200 μm inward from first covering member 211, for example, when forming resin sealing layer 108b in a wet film formation process, such as ink jetting, the opening inhibits the film formation, which uses the wetting and spreading of the resin sealing material. In this example, no opening is provided in a region that is 200 μm inward from metal layer 203, and therefore, the film formation can be achieved by taking advantage of the flowability of the resin sealing material. Therefore, resin sealing layer 108b can be appropriately formed, and entry of moisture into display device 1A can be suppressed.

### Other Forms

Although the display device according to the present disclosure is described above based on the foregoing embodiments, the present disclosure is not limited to the foregoing embodiments. The present disclosure includes forms obtained by various modifications to the foregoing embodiments that can be conceived by those skilled in the art without departing from the essence of the present disclosure, as well as various devices that are built into the display device according to the present disclosure.

Although opening 203b illustrated in the embodiment is in a slit-like shape, opening 203b is not limited to this. The opening may be rectangular, elliptic, or circular in shape, for example.

For example, organic EL element 150 may be formed by sequentially stacking a pixel electrode, a hole injection layer, an organic layer, an electron injection layer, and a counter electrode. Furthermore, a hole transport layer may be formed between the hole injection layer and the organic layer. An electron transport layer may be formed between the organic layer and the electron injection layer. To suppress electrons reaching the hole transport layer, an electron block layer may be formed between the hole transport layer and the organic layer.

### INDUSTRIAL APPLICABILITY

The display device according to an aspect of the present disclosure can be widely used in a device such as a television set, a personal computer, a mobile phone, or other various electronic devices having a display panel.

1. A display device comprising:
a substrate;
an interlayer insulating layer that is provided on a side corresponding to one principal surface of the substrate and includes a resin material;
an organic electroluminescent (EL) array that is provided on the interlayer insulating layer and includes a plurality of organic EL elements;
a metal layer that is provided on the interlayer insulating layer, the metal layer being connected to the organic EL array and disposed outward of the organic EL layer;
a covering member that is provided on the interlayer insulating layer, the covering member being disposed outward of the organic EL array and inward of a peripheral region of the interlayer insulating layer;
a lower inorganic sealing layer that is provided continuously on the organic EL array, the metal layer, and the covering member and extends up to the peripheral region of the interlayer insulating layer to cover the organic EL array, the metal layer, and the covering member;
a resin sealing layer that is provided inward of the peripheral region of the interlayer insulating layer and covering at least part of the lower inorganic sealing layer that is located on the organic EL array and the metal layer; and
an upper inorganic sealing layer that is provided continuously on the resin sealing layer and extends up to the peripheral region of the interlayer insulating layer to cover the resin sealing layer and overlap the lower inorganic sealing layer at the peripheral region of the interlayer insulating layer, wherein
at least part of a peripheral portion of the metal layer has a tapered cross-sectional shape that is convex in a direction opposite to a direction toward the one principal surface of the substrate, the peripheral portion being covered by the covering member.

2. The display device according to claim 1, wherein
a cross-sectional shape of the covering member is tapered and convex in the direction opposite to the direction heading toward the one principal surface of the substrate.

3. The display device according to claim 1, further comprising:
a bank provided to surround each of the plurality of organic EL elements, wherein
the covering member is made of same material as the bank.

4. The display device according to claim 1, wherein
the display device includes a first region and a second region located outward of the first region, the first region including a thin film transistor (TFT) layer of the substrate, and
when seen from a direction perpendicular to the substrate:
the covering member and the peripheral portion of the metal layer are located in the first region; and
the peripheral region of the interlayer insulating layer is located in the second region.

5. The display device according to claim 1, wherein
the covering member includes a first covering member located furthest outward and a second covering member located inward of the first covering member, and
the peripheral portion of the metal layer is located inward of the first covering member and is covered by the second covering member.

6. The display device according to claim 5, wherein
the metal layer includes an opening located inward of the peripheral portion of the metal layer,
the covering member further includes a third covering member located inward of the second covering member, and
the opening of the metal layer is covered by the third covering member.

7. The display device according to claim 5, wherein
the metal layer is not provided between the first covering member and the second covering member, and
the lower inorganic sealing layer, the resin sealing layer, and the upper inorganic sealing layer are stacked, in stated order, on the interlayer insulating layer.

8. The display device according to claim 1, wherein
the covering member includes a first covering member located furthest outward and a second covering member located inward of the first covering member, and
the peripheral portion of the metal layer is covered by the first covering member.

9. The display device according to claim 8, wherein
the metal layer includes an opening located inward of the peripheral portion of the metal layer, and
the opening of the metal layer is covered by the second covering member.

10. The display device according to claim 9, wherein
the opening is not provided between the first covering member and the second covering member,
the metal layer is provided throughout an entire area between the first covering member and the second covering member, and
the lower inorganic sealing layer, the resin sealing layer, and the upper inorganic sealing layer are stacked, in stated order, on the metal layer.

11. The display device according to claim 9, wherein
the opening is not provided in a region of the metal layer that is 200 μm inward from the first covering member, and the metal layer is provided in an entirety of the region.
